(19) United States
(12) Patent Application Publication
(10) Pub. No.: US 2012/0224419 A1
(43) Pub. Date: Sep. 6, 2012

(54) SEMICONDUCTOR STORAGE DEVICE

(75) Inventor: Satoshi INABA, Kanagawa (JP)

(73) Assignee: Kabushiki Kaisha Toshiba, Tokyo (JP)

(21) Appl. No.: 13/406,012

(22) Filed: Feb. 27, 2012

(30) Foreign Application Priority Data
Mar. 2, 2011 (JP) 2011-045213

(51) Int. Cl. G11C 11/40

(52) U.S. Cl. 365/182

(57) ABSTRACT

A semiconductor storage device according to an embodiment includes wells in a semiconductor substrate, fins formed on the wells, gate electrodes provided on one side and another opposite side of each fin via a gate insulating film to form a channel region in the fin, impurity-diffused layers that each form a potential barrier that confines holes in a body region within the channel region, and source/drain layers each formed at the fin such that the channel region is sandwiched between the source layer and the drain layer. At the time of writing of data ‘1’, a gate voltage is set to a negative potential, a well bias voltage is set to a positive potential, and a drain voltage is set to a positive potential.

### CROSS-REFERENCE TO RELATED APPLICATIONS

This application is based upon and claims the benefit of priority from Japanese Patent Application No. 2011-045213, filed on Mar. 2, 2011; the entire contents of which are incorporated herein by reference.

### FIELD

Embodiments described herein relate generally to semiconductor storage devices.

### BACKGROUND

In recent years, information storage devices (memories) formed on silicon substrates have been widely used in present personal computers, home appliances, digital cameras, and cellular phones, and that is because such memories have increased in capacity year by year, have come down in cost, and have offered enhanced performance.

Memories are classified into several types based on information storage capacity, access time, and so on; however, another type of memory has been developed. That is, as one of desirable memory devices high in capacity and capable of operating fast equivalent to dynamic memories (DRAMs), one-transistor memories have been studied and developed.

One-transistor memories, which are also called “capacitorless DRAM”, function as memories by causing a difference in reading current amounts by changing electric potential of the channel portion of one field effect transistor. The above method is equivalent to changing a threshold voltage at the field effect transistor with the change of the potential of the channel portion.

As one type of one-transistor memory, a memory in which a fin transistor is formed on a bulk substrate is provided. In this one-transistor memory, the potential of a channel portion is changed by forming a potential barrier against holes near the base of a fin and then confining holes generated by gate induced drain leakage (GIDL) in the fin. Incidentally, to improve the writing efficiency of such a one-transistor memory, it is important to efficiently generate holes by GIDL.

### BRIEF DESCRIPTION OF THE DRAWINGS

FIG. 1A is a schematic perspective view of a semiconductor storage device according to a first embodiment; FIG. 1B is a cross-sectional view of the semiconductor storage device of FIG. 1A taken along the line A-A; FIG. 1C is an illustration showing a P-type impurity concentration distribution and a potential distribution in the vertical direction within a fin 3 of FIG. 1B;

FIG. 2 is an equivalent circuit diagram of the semiconductor storage device of FIG. 1;

FIG. 3A is an illustration showing the state of a depletion layer in the vicinity of a drain layer D at the time of the generation of an interband tunnel current at the semiconductor storage device of FIG. 1; FIG. 3B is an illustration showing an energy band in the vicinity of the drain layer at the time of the generation of the interband tunnel current at the semiconductor storage device of FIG. 1;

FIG. 4 is a graph showing the relationship between gate voltage Vg and drain current Id at the time of the change of a substrate bias voltage at the semiconductor storage device of FIG. 1;

FIG. 5 is a graph showing the relationship between gate voltage Vg and gate leakage current Ig at the time of the change of a substrate bias voltage at the semiconductor storage device of FIG. 1;

FIG. 6A is a timing chart showing exemplary waveforms of gate voltages Vg, drain voltages Vd, and substrate bias voltages Vb at a write time period, a hold time period, and a read time period at the time of writing of data ‘1’; FIG. 6B is a timing chart showing exemplary waveforms of gate voltages Vg, drain voltages Vd, and substrate bias voltages Vb at a write time period, a hold time period, and a read time period at the time of writing of data ‘0’;

FIG. 7A is a timing chart showing other exemplary waveforms of gate voltages Vg, drain voltages Vd, and substrate bias voltages Vb at a write time period, a hold time period, and a read time period at the time of writing of data ‘1’; FIG. 7B is a timing chart showing other exemplary waveforms of gate voltages Vg, drain voltages Vd, and substrate bias voltages Vb at a write time period, a hold time period, and a read time period at the time of writing of data ‘0’;

FIG. 8 is a schematic block diagram of a semiconductor storage device according to a second embodiment;

FIG. 9 is a schematic perspective view of a semiconductor storage device according to a third embodiment;

FIG. 10 is a schematic plan view of the semiconductor storage device according to the third embodiment showing a layout of fins and gate electrodes; and

FIG. 11 is a schematic plan view of the semiconductor storage device according to the third embodiment showing a layout of fins, gate electrodes, wells, bit lines, and source lines.

### DETAILED DESCRIPTION

Semiconductor storage devices according to embodiments are each provided with a fin, gate electrodes, an impurity-diffused layer, and a source/drain layer. The fin is formed on a semiconductor substrate. Specifically, the two gate electrodes are respectively provided on one side and another opposite side of the fin via a gate insulating film. Within the fin is formed a channel region. Within the impurity-diffused layer is formed a potential barrier by which holes are confined in a body region within the channel region. The source/drain layer is formed in the fin such that the channel region is sandwiched in the source/drain layer. At the time of writing of data ‘1’, a gate voltage is set to a negative potential, a substrate bias voltage is set to a positive potential, and a drain voltage is set to a positive potential.

The semiconductor storage devices according to the embodiments will be described below with reference to the accompanying drawings. Note that the present invention is not limited the following embodiments.

### First Embodiment

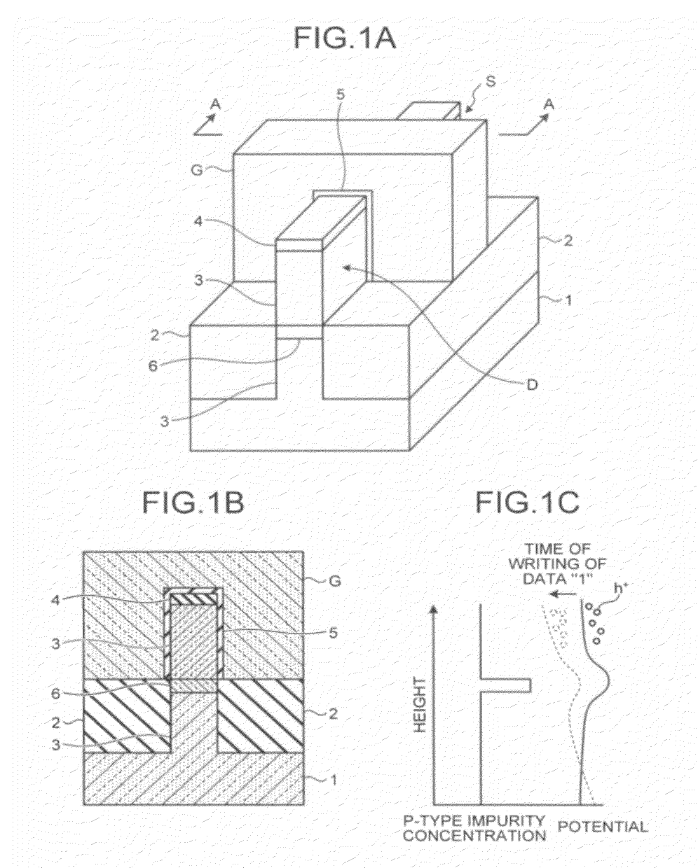

FIG. 1A is a schematic perspective view of a semiconductor storage device according to a first embodiment. FIG. 1B is a cross-sectional view of the semiconductor storage device of FIG. 1A taken along line A-A. FIG. 1C is a graph showing a P-type impurity concentration distribution and a potential distribution in the direction of the height of a fin 3 of FIG. 1B.

As shown in FIGS. 1A to 1C, the fin 3 is formed on a semiconductor substrate 1, and a capping layer 4 is formed on the fin 3. Incidentally, a material for the semiconductor substrate 1 can be selected from among materials such as Si, Ge, SiGe, GaAs, InP, GaP, InGaAs, GaN, and SiC. As a material for the capping layer 4, a silicon nitride, for example, can be used. And further, the conductivity type of the semiconductor substrate 1 and the fin 3 can be set to a P type. As an impurity of the P type, B, for example, can be used.

On the semiconductor substrate 1, embedded insulating layers 2 are formed on one side and another opposite side of the fin 3. And further, the height of the embedded insulating layers 2 can be set such that the upper portion of the fin 3 protrudes. In addition, as a material for the embedded insulating layers 2, a silicon oxide, for example, can be used.

On the embedded insulating layers 2, two gate electrodes G are respectively formed on one side and another opposite side of the fin 3 via a gate insulating film 5. And further, the gate electrodes G may be formed over the protrusion of the fin 3, i.e., the gate electrodes G on the opposite sides of the fin 3 may be combined together. In addition, as a material for the gate insulating film 5, a silicon oxide, for example, can be used. As a material for the gate electrode G, polycrystalline silicon, for example, can be used, or metallic compounds such a titanium nitride, a tantalum carbide, a lanthanum-based material, an aluminum-based material, and a magnesium-based material may be used singly or in combination.

Since the n-type fin FET is used in this embodiment, a P-type impurity-diffused layer 6 is formed between the STI upper end and the base of the fin 3. Incidentally, as the P-type impurity in the P-type impurity-diffused layer 6, B or In, for example, can be used. The concentration of the P-type impurity in the P-type impurity-diffused layer 6 is set in such a manner that the above concentration is made higher than the concentration of the P-type impurity in each fin 3, and a potential barrier BP can, therefore, be formed to confine holes h⁺ in a body region within the channel region of the fin 3. Note that it is preferable to dispose the P-type impurity-diffused layer 6 in a manner that does not overlap with the channel region in the fin 3 under the gate electrode G.

Within the fin 3, a drain layer D and a source layer S are formed in such a way that the channel region in the fin 3 is sandwiched between the drain layer D and the source layer S under the gate electrode 3. Incidentally, the conductivity type of each drain layer D and each source layer S can be set to the N type. As an impurity of the N type, P or As, for example, can be used.

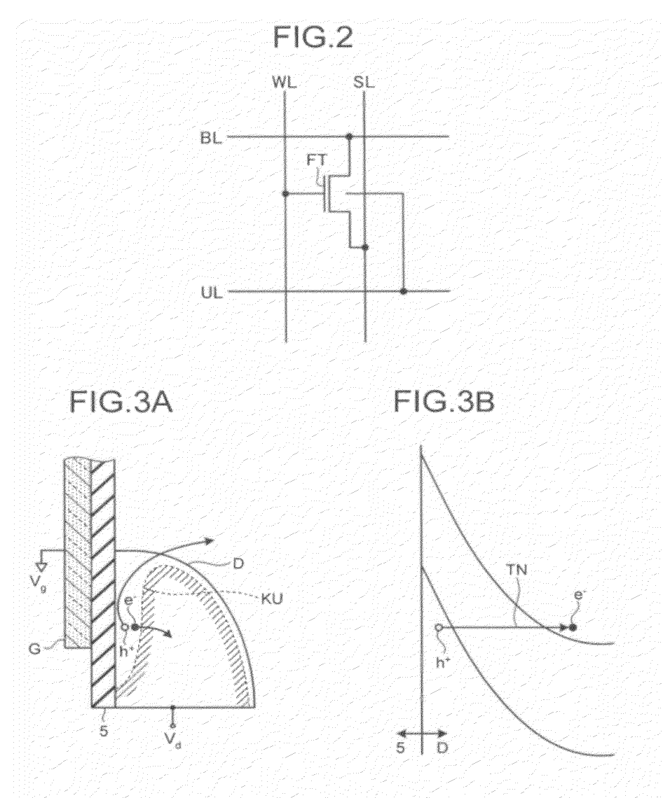

FIG. 2 is an equivalent circuit diagram of the semiconductor storage device of FIG. 1.

As shown in FIG. 2, the gate electrode G, the drain layer D, and the source layer S of FIG. 1 constitute one fin transistor FT: the gate electrode G is coupled to a word line WL, the drain layer D is coupled to a bit line BL, and the source layer S is coupled to a source line SL, and the semiconductor substrate 1 is coupled to a substrate bias line UL. To the word line WL, a gate voltage Vg can be provided; to the bit line BL, a drain voltage Vd can be provided; to the source line SL, a source voltage Vs can be provided; to the substrate bias line UL, a substrate bias voltage Vb can be provided.

Operation of the semiconductor storage device of FIG. 1 will be described below. In the following description, a state in which holes have been confined in the body region within the channel region of the fin 3 is assumed to be a state in which data ‘1’ has been written, and a state in which holes have been released from the body region is assumed to be a state in which data ‘0’ has been written.

In the case of writing data ‘1’ into the semiconductor storage device, a gate voltage Vg is set to a negative potential, a substrate bias voltage Vb is set to a positive potential, a drain voltage Vd is set to a positive potential, and a source voltage Vs is set to a ground potential.

When the gate voltage Vg has been set to the negative potential at the time of the writing, the fin transistor FT is turned off, a depletion layer in the vicinity of the drain layer D is curved to some extent, the application of a strong electric field results, and thus an interband tunnel current flows. Due to the interband tunnel current, GILD occurs.

FIG. 3A is an illustration showing the state of a depletion layer in the vicinity of the drain layer D at the time of the generation of an interband tunnel current at the semiconductor storage device of FIG. 1: FIG. 3B is an illustration showing an energy band in the vicinity of the drain layer D at the time of the generation of the interband tunnel current at the semiconductor storage device of FIG. 1.

As shown in FIG. 3A, after the setting of the gate voltage Vg to the negative potential and the setting of the drain voltage Vd to the positive potential, the depletion layer KU in the vicinity of the drain layer D is curved to some extent, and a strong electric field is applied. Therefore, as shown in FIG. 3B, an interband tunnel current TN flows into the depletion layer KU, and pairs of holes h⁺ and electrons e⁻ form. The holes h⁺ of the pairs are confined in the body region within the fin 3 by the potential barrier BP, and data ‘1’ is written by GIDL.

In the case of data ‘0’ is written to the semiconductor storage device, a gate voltage Vg and a source voltage Vs are set to the ground potential, a substrate bias voltage Vb is set to the ground potential or a negative potential, and a drain voltage Vd is set to a negative potential. As a result, holes h⁺ accumulated in the body region within the channel region of the fin 3 are released into the drain layer D, and the data ‘0’ is therefore written.

When holes h⁺ are confined in the body region within the channel region of the fin 3, the potential of the body region becomes high to the positive side as compared with the time when no holes h⁺ are confined. Because of this, at the time when holes h⁺ are confined in the body region within the channel region of the fin 3, the gate voltage Vg (i.e., a threshold Vt) at which the fin transistor FT begins to change to the ON state is low as compared with the time when no holes h⁺ are confined in the body region, and thus the amount of a current that flows when the same gate voltage Vg has been applied becomes large. By detecting the difference in current amount between the case when the holes h⁺ are confined in the body region and the case where no holes h⁺ are confined in the body region, data stored in the semiconductor storage device of FIG. 1 can be determined to be ‘1’ or ‘0’.

In the method of writing data ‘1’ by GIDL, since the gate voltage Vg is set to the negative potential, the potential of the side of the holes h⁺ in the channel region is lowered as shown in FIG. 1C. Thus the holes h⁺ cannot easily escape to the side of the semiconductor substrate 1, and an enhanced writing efficiency can, therefore, be achieved.

At the time of writing of data ‘1’ using GIDL, by setting the substrate bias voltage Vb to the positive potential, the amount of the GIDL can be increased while suppressing an increase in the absolute value of the gate voltage Vg. And further, by making such setting, the amount of a gate leakage current can be reduced as compared with the case where the substrate bias voltage Vb is set to the ground potential, and an enhanced writing efficiency is therefore achieved.

In the above case, the components of the gate leakage current Ig and the components of a drain current Id in the state of being accumulated in the field effect transistor can respectively be expressed by the following expressions (1) and (2).

Ig(L,Vg,Vb)=Igch(L,Vg,Vb)+Igs+Igd (1)

Id(L,Vg,Vb)=Igd+IGIDL(Vg,Vb)+IJL (2)

With Expression (1), “Igs+Igd” represents a gate leakage current generated at a portion where the gate electrode G, the source layer S, and the drain layer D overlap one another; “Igch” represents a gate leakage current generated at a portion between the channel region and the gate electrode G, and is generally a function composed of a gate length L, a gate voltage Vg, and a substrate bias voltage Vb.

With Expression (2), components observed as the drain current Id are the gate leakage current Igd, a junction leakage current IJL, and a current IGIDL (Vg, Vb) generated by GIDL.

In this case, the amount of the interband tunnel current TN depends on the width of the depletion layer KU and the strength of the electric field, and is therefore affected by the profiles of the impurity in the drain layer D. In the case where the concentration of the impurity in the drain layer D is too high, the depletion layer KU does not curve due to the gate voltage Vg; in the case where the concentration of the impurity in the drain layer D is too low, the width of the depletion layer KU becomes large and hence, interband tunneling is less likely to occur. Therefore, by suitably utilizing the profiles of the impurity in the drain layer D and the profiles of the impurity in a portion near the channel region in the vicinity of the drain layer D, GIDL at the time when having fixed the gate voltage Vg can be increased.

Since the fin transistor FT is a double-gate transistor, a lessened short channel effect can be achieved, and a reduction of variations in the characteristics of the transistor due to the profiles of the substrate impurity can be implemented; and moreover, such a structure is suitable for further miniaturization of memories.

Since the fin transistor FT performs as a complete-depletion channel device, Vt (threshold) characteristics do not vary even when a substrate bias voltage Vb is applied. Since the fin transistor FT including the bulk substrate, in particular, does not include a buried oxide (BOX) layer for an SOI, when a substrate voltage Vb is applied, the applied substrate bias voltage Vb can be directly fed to the fin 3. However, Id-Vg characteristics in a gate voltage range exhibited across a depletion region (in which complete depletion occurs) and an inversion region (an inversion layer which is formed in the channel region and in which minority carriers are present) depend substantially on the shape (the width) of the fin 3 and a work function at the gate electrode G.

In contrast, in the case where a negative voltage is applied to the gate electrode G to bring about a state of being accumulated at the channel region (to form a layer in which majority carriers are accumulated in the channel region), by applying a substrate bias voltage Vb to the fin transistor FT including the bulk substrate, distinctive drain current characteristics can be observed.

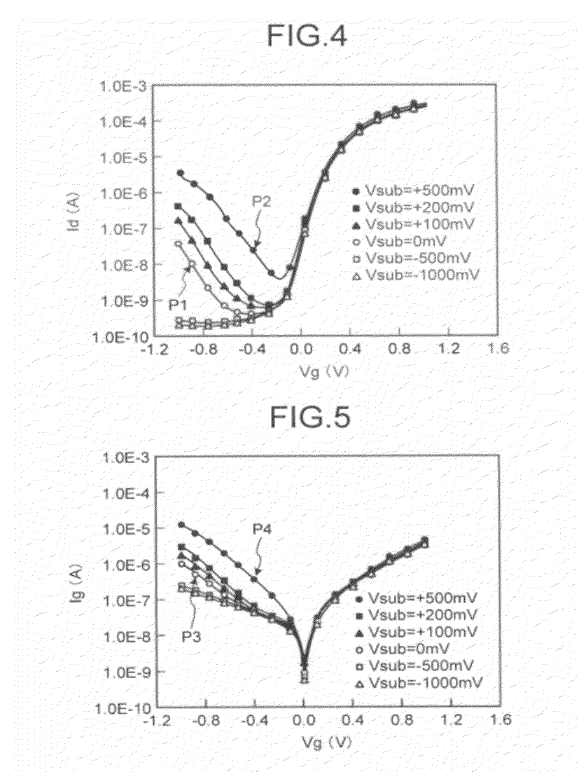

FIG. 4 is a graph showing the relationship between gate voltage Vg and drain current Id at the time when a substrate bias voltage at the semiconductor storage device of FIG. 1 has been changed. Incidentally, drain voltage Vd is fixed at 1.0 V.

As shown in FIG. 4, in the case where a negative voltage has been applied to the gate electrode G to bring about a state of being accumulated at the channel region, the application of positive substrate bias voltages Vb makes the drain current Id large, but the application of negative substrate bias voltages Vb makes the drain current Id small.

In contrast, in the case where a positive voltage has been applied to the gate electrode G to bring about an inversion state at the channel region, the drain current Id does not change even when a substrate bias voltage Vb has been changed.

FIG. 5 is a graph showing the relationship between gate voltage Vg and gate leakage current Ig at the time when a substrate bias voltage at the semiconductor storage device of FIG. 1 has been changed. Incidentally, drain voltage Vd is fixed at 1.0 V.

As shown in FIG. 5, in the case where a negative voltage has been applied to the gate electrode G to bring about a state of being accumulated at the channel region, the application of positive substrate bias voltages Vb makes the gate leakage current Ig large, but the application of negative substrate bias voltages Vb makes the gate leakage current Ig small.

In contrast, in the case where a positive voltage has been applied to the gate electrode G to bring about an inversion state at the channel region, the gate leakage current Ig does not change even when a substrate bias voltage Vb has been changed.

Here the present inventors have attempted to consider two cases where it can be thought that electric fields applied at a portion between the gate electrode G and the semiconductor substrate 1 are identical. For example, a point P3 (at which Vb=−0.9 V, and Vb=0.0 V) and a point P4 (at which Vg=−0.4 V, and Vb=0.5 V) are compared. In that case, a voltage applied to the source layer S (Vs) is 0.0 V, and a voltage applied to the drain layer D (Vd) is 1.0 V. Since the gate voltage Vg with respect to the semiconductor substrate 1 is −0.9 V at both the points, the gate leakage currents Ig should be identical.

However, as shown in FIG. 5, a gate leakage current Ig at the point P3 is large compared with a gate leakage current Ig at the point P4 in reality. In can be considered that this is because at a region where the source layer S or the drain layer D overlaps with the gate electrode G, by setting Vg to −0.9 V, a strong electric field is applied as compared with the setting of Vg to −0.4 V (plus Vb of 0.5 V), and therefore gate leakage currents Igs and Igd in Expression (1), in particular, a gate leakage current Igd increase. That is, from the comparison of the two bias conditions, it is determined that the Igd component makes a perceptible contribution.

Then a point P1 (at which Vg=−0.9 V, and Vb=0.0 V) and a point P2 (at which Vg=−0.4 V, and Vb=0.5 V) in FIG. 4 are compared. As a result, it can be seen with respect to observed drain currents Id that a gate leakage current Ig at the point P2 is large compared with a gate leakage current Ig at the point P1. This suggests that it is determined from Expression (2) that in the case where Vg=−0.9 V, since the Igd component of which amount should have been increased of the components of each drain current Id is too small to detect as compared with the other components, the amount of a drain current Id depends on the amounts of IGIDL and a junction leakage current IJL.

Since the comparison has been made using a fixed drain voltage, the contribution of the junction leakage current IJL should also be small. If the junction leakage current IJL is the dominant component of the drain current Id, the value of the drain current Id should be nearly constant because the Vg dependence of the current component IJL is low. The above value, however, is not constant in reality and it can be seen that the Vg dependence of the drain current Id is considerably high. Therefore the IGIDL component is presumed to be the dominant component of the drain current Id.

From the above, it is apparent that in order to increase the ratio of the IGIDL component with the gate voltage Vg fixed, the substrate bias voltage Vb may be set to a positive potential. An example of interpretations of such a phenomenon is that having set the substrate bias voltage Vb to the positive potential brings about a state in which the width of the drain depletion layer becomes small, and thus GIDL further tends to occur and a state in which since generated holes escape to the semiconductor substrate becomes less likely, the potential of the body region moves to the positive side more and more, potential feedback due to the movement is given, and the positive substrate bias voltage Vb is therefore applied more effectively.

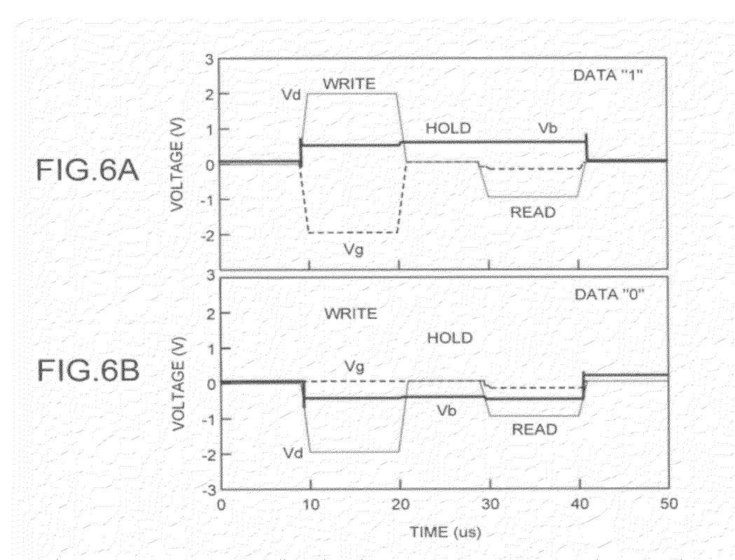

FIG. 6A is a timing chart showing exemplary waveforms of gate voltages Vg, drain voltages Vd, and substrate bias voltages Vb at a write time period, a hold time period, and a read time period at the time of writing of data ‘1’; FIG. 6B is a timing chart showing exemplary waveforms of gate voltages Vg, drain voltages Vd, and substrate bias voltages Vb at a write time period, a hold time period, and a read time period at the time of writing of data ‘0’

As shown in FIG. 6A, at the write time period for storing data ‘1’, the gate voltage Vg, the substrate bias voltage Vb, the drain voltage Vd, and source voltage Vs are respectively set to −2 V, 0.5 V, 2 V, and 0 V, for example.

At the write time period, holes h⁺ generated by GIDL are confined in the body region within the channel region of the fin 3 by the potential barrier BP, and data ‘1’ is thus written.

At the hold time period for storing the data ‘1’ after the write, the gate voltage Vg, the drain voltage Vd, and the source voltage Vs are set to 0 V, and the substrate bias voltage Vb is set to 0.5 V, for example.

At the hold time period, the holes h⁺ generated by the GIDL are held confined in the body region within the channel region of the fin 3 by the potential barrier BP.

At the read time period for storing the data ‘1’ after the hold, the gate voltage Vg, the drain voltage Vd, the source voltage Vs, and the substrate bias voltage Vb are respectively set to −0.05 V, −1 V, 0 V, and 0.5 V, for example.

At the read time period during which the holes h⁺ are confined in the body region within the channel region of the fin 3, as compared with the time when no holes h⁺ are confined, the threshold Vt lowers, and the amount of current flowing within the fin transistor FT increases. Although FIG. 6A shows the case where the substrate bias voltage Vb is changed at the write time period, the hold time period, and the read time period by way of example, a fixed voltage may be applied.

On the other hand, at the write time period for storing the data ‘0’, as shown in FIG. 6B, gate voltage Vg and source voltage Vs are set to 0 V, substrate bias voltage Vb is set to −0.5 V, and drain voltage Vd is set to −2 V, for example.

At the write time period, holes h⁺ accumulated in the body region within the channel region of the fin 3 are released to the drain layer D, and data ‘0’ is thus written. Incidentally, by setting the substrate bias voltage Vb to a negative potential at the write time period for storing data ‘0’, holes h⁺ accumulated in the body region within the channel region of the fin 3 can escape to the semiconductor substrate 1 easily, and data ‘0’ can, therefore, be written efficiently.

At the hold time period for storing the data ‘0’ after the write, the gate voltage Vg, the drain voltage Vd, and the source voltage Vs are set to 0 V, and the substrate bias voltage Vb is set to −0.5 V, for example.

After the setting, the holes h⁺ are held released from the body region within the channel region of the fin 3.

At the read time period for storing the data ‘0’ after the hold, the gate voltage Vg, the drain voltage Vd, the substrate bias voltage Vb, and the source voltage Vs are respectively set to −0.05 V, −1 V, −0.5 V, and 0 V, for example.

At the time when holes h⁺ are confined in the body region within the channel region of the fin 3 at the read time period, as compared with the time when no holes h⁺ are confined, the threshold Vt heightens, and the amount of current flowing within the fin transistor FT reduces.

Although FIG. 6B also shows having changed the substrate bias voltage Vb at the write time period, the hold time period, and the read time period by way of example, a fixed substrate bias voltage Vb may be applied.

By applying the substrate bias voltage Vb used at the write time period, at the hold time period and the read time period as it is, a state in which a write body potential is established is held easily even when either data ‘1’ or data ‘0’ is written, and read disturbance can also be suppressed.

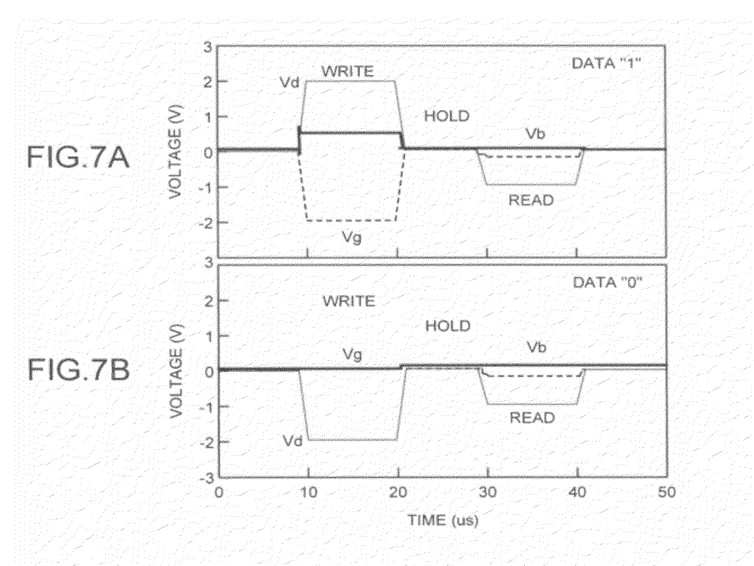

FIG. 7A is a timing chart showing other exemplary waveforms of gate voltages Vg, drain voltages Vd, and substrate bias voltages Vb at a write time period, a hold time period, and a read time period at the time of writing of data ‘1’; FIG. 7B is a timing chart showing other exemplary waveforms of gate voltages Vg, drain voltages Vd, and substrate bias voltages Vb at a write time period, a hold time period, and a read time period at the time of writing of data ‘0’.

In FIGS. 6A and 6B, the substrate bias voltages Vb have been set to 0.5 V at the write time period, the hold time period, and the read time period for storing the data ‘1’, and the substrate bias voltages Vb has been set to −0.5 V at the write time period, the hold time period, and the read time period for storing the data ‘0’. On the other hand, in FIG. 7A, after the setting of the substrate bias voltage Vb to 0.5 V at the write time period for storing the data ‘1’, the substrate bias voltage Vb is changed to 0 V at the hold time period and the read time period; in FIG. 7B, the substrate bias voltage is set to 0 V at the write time period, the hold time period, and the read time period for storing the data ‘0’.

As can be seen from the above, substrate bias voltage Vb can be applied only at the write time period for storing data ‘1’, and there is no need to hold information on the substrate bias voltage Vb with regard to a written bit data, whereby control of data writing can be simplified, and reduced power consumption can be implemented.

Although the method of setting the substrate bias voltage Vb to 0 V at the time periods other than the write time period for storing data ‘1’ has been described with reference to FIGS. 7A and 7B, a very small positive voltage of about 0.1 V may be applied to improve data hold characteristics at the time of writing of data ‘1’.

Moreover, although the method of directly forming the fin 3 from the semiconductor substrate 1 has been described in this embodiment, a well may be formed in the semiconductor substrate 1 to form the fin 3 from the well. In that case, well bias voltage may be applied to the well instead of substrate bias voltage Vb.

### Second Embodiment

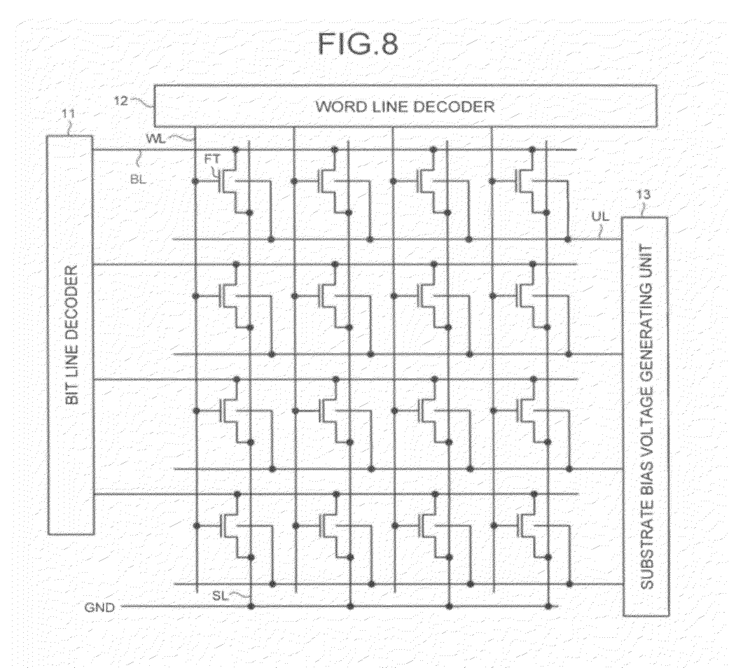

FIG. 8 is a schematic block diagram of a semiconductor storage device according to a second embodiment. In FIG. 8, the fin transistors FT are arranged in four rows and four columns.

In the semiconductor storage device according to the second embodiment, as shown in FIG. 8, the fin transistors FT are disposed in matrix form, i.e., in the row direction and the column direction. Word lines WL are coupled to a word line decoder 12, bit lines BL are coupled to a bit line decoder 11, substrate bias lines UL are coupled to a substrate bias voltage generating unit 13, and source lines SL are coupled to a ground potential GND.

The bit line decoder 11 is capable of applying a drain voltage Vd to the bit line BL in the selected row. The word line decoder 12 is capable of applying a gate voltage Vg to the word line WL in the selected column. The substrate bias voltage generating unit 13 is capable of applying a substrate bias voltage Vb to the substrate bias line UL in the selected column.

A write operation and a read operation are performed by applying a gate voltage Vg via the word line WL to the gate electrode G of the cell selected by the bit line decoder 11 and the word line decoder 12, by applying a drain voltage Vd to the drain layer D via the bit line BL, and applying the substrate bias voltage Vb to the semiconductor substrate 1 via the substrate bias line UL.

By making the fin transistors FT in the same row share the substrate bias line UL, it becomes unnecessary to individually apply a substrate bias voltage Vb to the fin transistors FT in the row, and a reduced circuit size can, therefore, be achieved.

### Third Embodiment

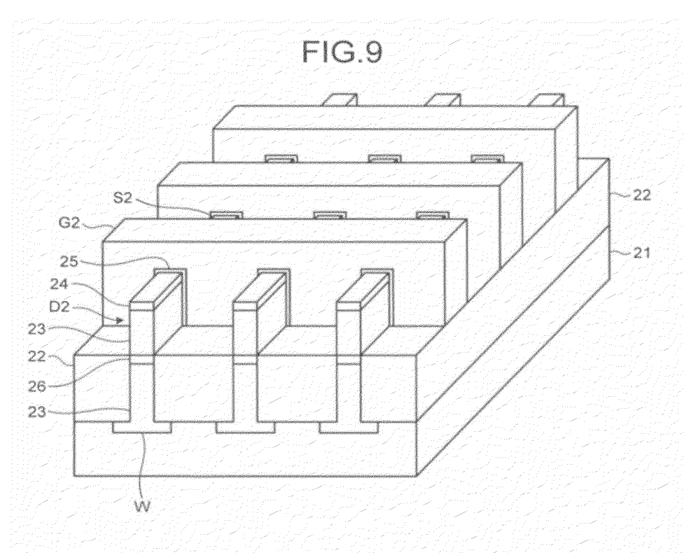

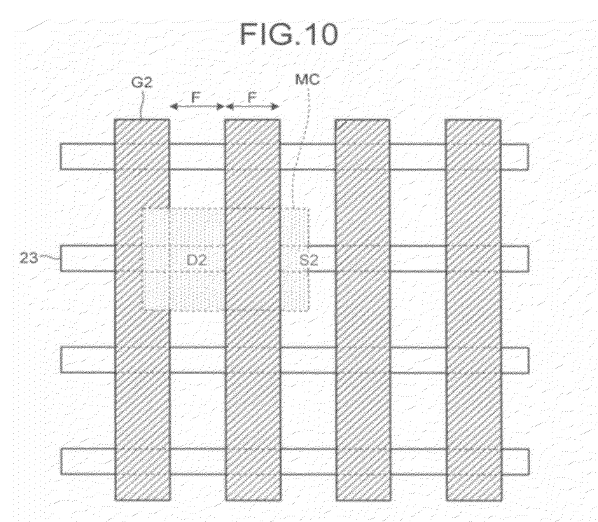

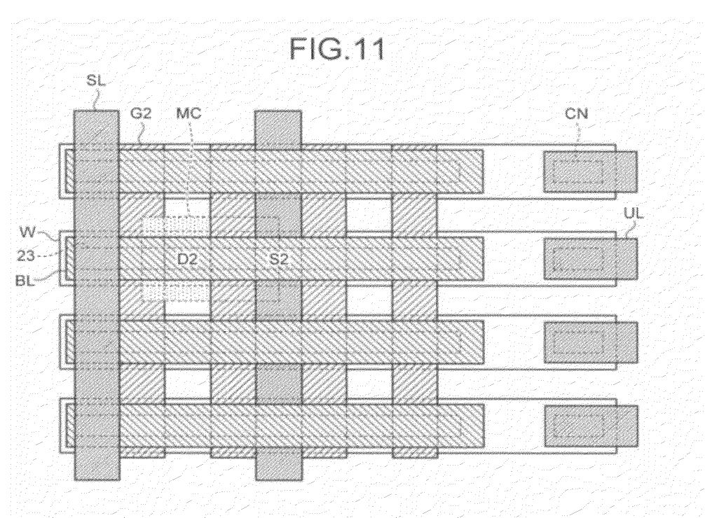

FIG. 9 is a schematic perspective view of a semiconductor storage device according to a third embodiment, FIG. 10 is a schematic plan view of the semiconductor storage device according to the third embodiment showing a layout of fins and gate electrodes, and FIG. 11 is a schematic plan view of the semiconductor storage device according to the third embodiment showing a layout of the fins, the gate electrodes, wells, bit lines, and source lines. Incidentally, in FIG. 9, fin transistors are arranged in three rows and three columns; in FIGS. 10 and 11, fin transistors arranged in four rows and four columns.

As shown in FIGS. 9 to 11, a plurality of wells W are formed in a semiconductor substrate 21 and a fin 23 is formed on each well W. On each fin 23, a capping layer 24 is formed. Incidentally, the conductivity type of the semiconductor substrate 21 can be set to the N type, and the conductivity type of the wells W and the fins 23 can be set to the P type. As an impurity of the N type, P or As, for example, can be used; as an impurity of the P type, B for example, can be used. And further, each fin 23 can be disposed along the well W. Furthermore, on the semiconductor substrate 21, embedded insulating layers 22 are formed between the fins 3.

On the embedded insulating layers 22, gate electrodes G2 are formed such that each gate electrode G2 is disposed on one side and another opposite side of the fin 23 via a gate insulating film 25. Between the upper end and the base of each fin 3, a P-type impurity-diffused layer 26 is formed.

At each fin 23, a drain layer D2 and a source layer S2 are formed such that a channel region in the fin 23 is sandwiched between both the layers D2 and S2 under the gate electrode G2: the pair of drain layer D2 and source layer S2 at each fin 23 are shared by the two neighboring fin transistors FT on the same fin 23. Incidentally, the conductivity type of the drain layers D2 and the source layer S2 can be set to the N type. In addition, at an end of each well W, a well contact CN is formed.

The gate electrodes G2 are coupled to word lines W, the drain layers D2 are coupled to bit lines BL, the source layers S2 are coupled to source lines SL, and the wells W are coupled to substrate bias lines UL via the well contacts CN. Incidentally, as the bit lines BL, the source lines SL, and the substrate bias lines UL, metal interconnects, such as Al interconnects or Cu interconnects, can be used.

By making the fin transistors FT formed on the same fin 23 share the well W, it becomes unnecessary to form the well contact CN at each transistor FT, and the memory cells each having a reduced area can, therefore, be implemented. For example, in the case where the well W is shared by the fin transistors FT formed on the same fin 23, since the pair of drain layer D2 and source layer S2 at each fin 23 can be shared by the two neighboring fin transistors FT, the area of the memory cell MC of FIG. 10 can be given by a multiplication 2F×3F=6F² (where F represents the width of and the spacing between the word lines WL), and the above area can, therefore, be made smaller than or equal to the areas of DRAMs (6F² to 8F²). On the other hand, in the case where the well contact CN is formed at each fin transistor FT, the area of each memory cell MC is given by a multiplication 2F×5F=10F², and thus becomes larger than the areas of DRAMs (6F² to 8F²).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
wells formed in a semiconductor substrate;
fins formed on the wells;
gate electrodes disposed on one side and another opposite side of each fin via gate insulating films to form a channel region in the fin;
impurity-diffused layers that form potential barriers that confine holes in body regions within the channel regions; and
source/drain layers formed in the fins such that the channel region is sandwiched between the source layer and the drain layer,
wherein at the time of writing of data ‘1’, a gate voltage is set to a negative potential, and a well bias voltage is set to a positive potential, and a drain voltage is set to a positive potential.

2. The semiconductor storage device according to claim 1, wherein data ‘1’ is written by confining holes generated by GIDL in the fin.

3. The semiconductor storage device according to claim 1, wherein at a write time period for storing data ‘0’, the gate voltage is set to a ground potential, the well bias voltage is set to the ground potential or a negative potential, and the drain voltage is set to a negative potential.

4. The semiconductor storage device according to claim 3, wherein data ‘0’ is written by releasing holes confined in the fin.

5. The semiconductor storage device according to claim 1, wherein the wells are disposed along the fins.

6. The semiconductor storage device according to claim 5, wherein the plurality of fins are formed in parallel in a row direction, the plurality of gate electrode are formed in parallel in a column direction such that the gate electrodes and the fins cross each other, a drain or a source layer is formed at the fin between the gate electrodes, and the wells are separated each other for each of the fins.

7. The semiconductor storage device according to claim 1, the device further comprising:
bit lines disposed along the fins and coupled to the drain layer;
word lines perpendicular to the fins and coupled to the gate electrode;
source lines perpendicular to the fins and coupled to the source electrode;
a bit line decoder that applies the drain voltage to the bit line in the selected row;
a word line decoder that applies the gate voltage to the word line in the selected column; and
a substrate bias voltage generating unit that applies the well bias voltage to the well in the selected column.

8. The semiconductor storage device according to claim 3, wherein the well bias voltage set to a write time period is held at a hold time period and a read time period as it is.

9. The semiconductor storage device according to claim 1, wherein the well bias voltage is reset to the ground potential or to a negative potential at a hold time period and a read time period.

10. The semiconductor storage device according to claim 1, the device further comprising embedded insulating layers embedded between the fins to separate the impurity-diffused layer.

11. The semiconductor storage device according to claim 10, wherein the upper ends of the impurity-diffused layer are flush with the top surfaces of the embedded insulating layers.

12. The semiconductor storage device according to claim 11, wherein the lower ends of the gate electrodes are flush with the upper ends of the impurity-diffused layers.

13. A semiconductor storage device comprising:
a fin formed on a semiconductor substrate;
gate electrodes provided on one side and another opposite side of the fin via the gate insulating film to form a channel region in the fin;
an impurity-diffused layer that forms a potential barrier that confines holes in a body region within the channel region; and
a source/drain layer formed at the fin such that the channel region is sandwiched between the source layer and the drain layer,
wherein when data ‘1’ is written, a gate voltage is set to a negative potential, a substrate bias voltage is set to a positive potential, and a drain voltage is set to a positive potential.

14. The semiconductor storage device according to claim 13, wherein data ‘1’ is written by confining holes generated by GIDL in the fin.

15. The semiconductor storage device according to claim 13, wherein at the time of writing of data ‘0’, the gate voltage is set to a ground potential, the substrate bias voltage is set to the ground potential or to a negative potential, and the drain voltage is set to a negative potential.

16. The semiconductor storage device according to claim 15, wherein data ‘0’ is written by releasing holes confined in the fin

17. The semiconductor storage device according to claim 13, the device further comprising:
bit lines disposed along the fins and coupled to the drain layer;
word lines perpendicular to the fins and coupled to the gate electrode;
source lines perpendicular to the fins and coupled to the source electrode;
a bit line decoder that applies the drain voltage to the bit line in the selected row;
a word line decoder that applies the gate voltage to the word line in the selected column; and
a substrate bias voltage generating unit that applies the well bias voltage to the well in the selected column.

18. The semiconductor storage device according to claim 15, wherein the substrate bias voltage set to a write time period is held at a hold time period and a read time period as it is.

19. The semiconductor storage device according to claim 13, wherein the substrate bias voltage is reset to the ground potential or a negative potential at a hold time period and a read time period.

20. The semiconductor storage device according to claim 13, the device further comprising embedded insulating layers embedded between the fins to separate the impurity-diffused layer.
